(19) United States
(12) Patent Application Publication
(10) Pub. No.: US 2019/0207530 A1
(43) Pub. Date: Jul. 4, 2019

(54) POWER SUPPLY CIRCUIT

(71) Applicant: FUJITSU LIMITED, Kawasaki-shi (JP)

(72) Inventor: Tatsuya Hirose, Yokohama (JP)

(73) Assignee: FUJITSU LIMITED, Kawasaki-shi (JP)

(21) Appl. No.: 16/353,272

(22) Filed: Mar. 14, 2019

Related U.S. Application Data
(63) Continuation of application No. PCT/JP2018/008298, filed on Mar. 5, 2018.

(30) Foreign Application Priority Data
Apr. 7, 2017 (JP) 2017-076614

(51) Int. Cl. H02M 7/12; H02M 1/34; H03F 3/21

(52) U.S. Cl. CPC H02M 7/12; H03F 3/21; H02M 1/34

(57) ABSTRACT

A power supply circuit includes a transformer that includes a primary winding and a first secondary winding, a first diode coupled to the first secondary winding in series, a first node, coupled to the primary winding, for receiving a supplied voltage, a second node coupled to a series connection circuit, the series connection circuit is including the first secondary winding and the first diode coupled to the first secondary winding in series, a first capacitor coupled to the second node, a first resistor coupled between the first node and the second node; and a driving circuit that includes a power supply terminal coupled to the second node.

### CROSS-REFERENCE TO RELATED APPLICATION

This application is a continuation application of International Application PCT/JP2018/008298 filed on Mar. 5, 2018 and designated the U.S., the entire contents of which are incorporated herein by reference. The International Application PCT/JP2018/008298 is based upon and claims the benefit of priority of the prior Japanese Patent Application No. 2017-076614, filed on Apr. 7, 2017, the entire contents of which are incorporated herein by reference.

### FIELD

The embodiments discussed herein are related to a power supply circuit.

### BACKGROUND

A power supply circuit that includes a transformer, a switching transistor, and a power supply controller is known. A primary coil of the transformer has a terminal to which a rectified and smoothed input alternating voltage of an alternating-current power supply is supplied. The terminal of the primary coil is connected to a power supply terminal. The switching transistor has a drain terminal connected to another terminal of the primary coil. The switching transistor has a source terminal connected to a ground-side power supply terminal via a first resistor for current value detection. The power supply controller is connected to a gate terminal of the switching transistor and turns on and off the switching transistor based on a predetermined oscillation frequency. A voltage of an output unit that has been input to a first feedback unit is input to the power supply controller. A voltage generated across the first resistor for the current value detection is input to the power supply controller. The power supply controller controls, based on the voltages input to the power supply controller, the ratio of a time period during which the switching transistor is turned on to a time period during which the switching transistor is turned off. By controlling the ratio, the power supply controller controls a current that flows in the switching transistor. The power supply controller switches an operational state of the switching transistor between a clock operation and a constant-current operation.

An initial activation circuit for a power supply device, which includes a rectifying unit, a switching unit, a transforming unit, an activating unit, a driving unit, an output unit, and a controller, is known. The rectifying unit rectifies an input voltage. The rectified voltage output from the rectifying unit is applied to the switching unit, whereby the switch unit is switched. The transforming unit induces the voltage used for the switching of the switching unit from a main winding to an auxiliary winding and a secondary winding. The activating unit is installed between the switching unit and the transforming unit and activates the switching unit by a distributing unit for distributing a voltage applied via the main winding of the transforming unit. The driving unit controls the switching unit by receiving a voltage from the auxiliary winding of the transforming unit. The output unit rectifies a voltage output from the secondary winding of the transforming unit to generate a smoothed output voltage and senses the output voltage. The controller receives a signal sensed by the output unit and switches the switching unit. This reduces power to be consumed by the initial activation circuit for the power supply device and enables the initial activation circuit to stably operate against an overvoltage and an overcurrent.

In conventional MO technology, since the oscillation frequency is fixed, a switching frequency of the switching transistor is fixed. In recent years, it is desirable that the size and weight of a power supply including magnetic components such as a coil and a transformer be small. To enable the power supply, the switching transistor is to be switched at a high speed. In a circuit including a related-art silicon semiconductor, an oscillation frequency is low and fixed and it is difficult to change a switching speed of the switching transistor.

A control integrated circuit (IC) controls a gate voltage of the switching transistor. A power supply voltage is to be supplied to a power supply terminal of the control IC. In a related-art method, however, a special auxiliary power supply is installed in another system in order to supply a power supply voltage in a stable manner upon the activation of a power supply circuit. Thus, the other power supply is to be activated to activate the power supply, the number of components forming the power supply is increased, power to be consumed due to the auxiliary power supply increases, and a power conversion efficiency of the entire power supply is not improved. If the special auxiliary power supply is not installed, the power supply voltage is not stably generated and it is difficult to supply the power supply voltage to the power supply terminal of the control IC.

The followings are reference documents.

[Document 1] Japanese Laid-open Patent Publication No. 2012-221991 and

[Document 2] Japanese Laid-open Patent Publication No. H10-323030.

### SUMMARY

According to an aspect of the embodiments, a power supply circuit includes a transformer that includes a primary winding and a first secondary winding, a first diode coupled to the first secondary winding in series, a first node, coupled to the primary winding, for receiving a supplied voltage, a second node coupled to a series connection circuit, the series connection circuit is including the first secondary winding and the first diode coupled to the first secondary winding in series, a first capacitor coupled to the second node, a first resistor coupled between the first node and the second node; and a driving circuit that includes a power supply terminal coupled to the second node.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an example of a configuration of a power supply circuit according to a first embodiment;

FIG. 2 is a diagram illustrating an example of a configuration of a transformer;

FIG. 3A is a conceptual diagram illustrating an example of a configuration of a primary control IC;

FIG. 3B is a voltage waveform diagram describing operations of the primary control IC;

FIG. 4 is a diagram illustrating an example of a configuration of a power supply circuit according to a second embodiment; and

FIG. 5 is a diagram illustrating an example of a functional configuration of the power supply circuit according to the first embodiment.

### DESCRIPTION OF EMBODIMENTS

### First Embodiment

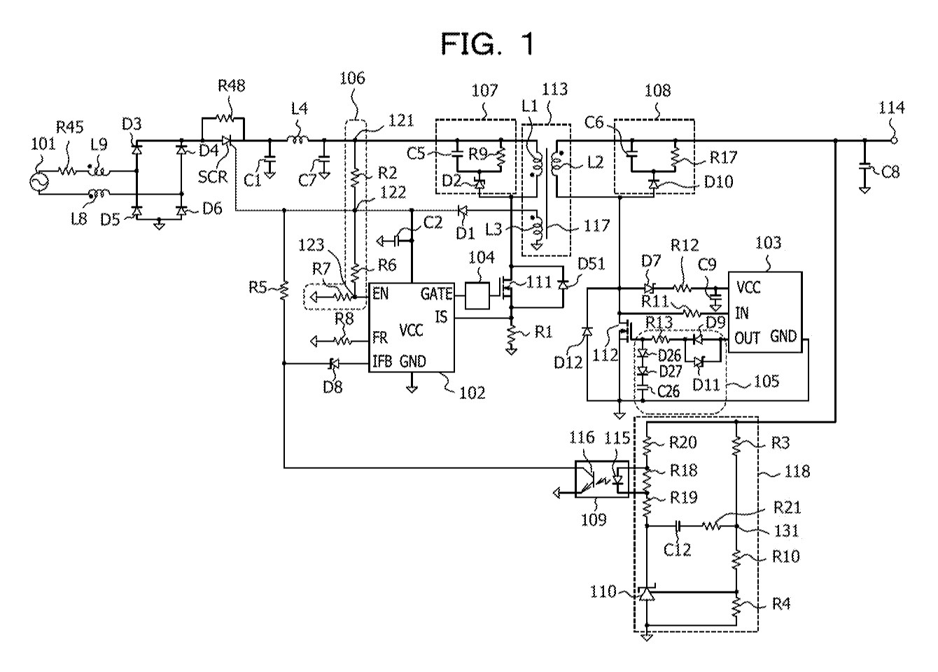

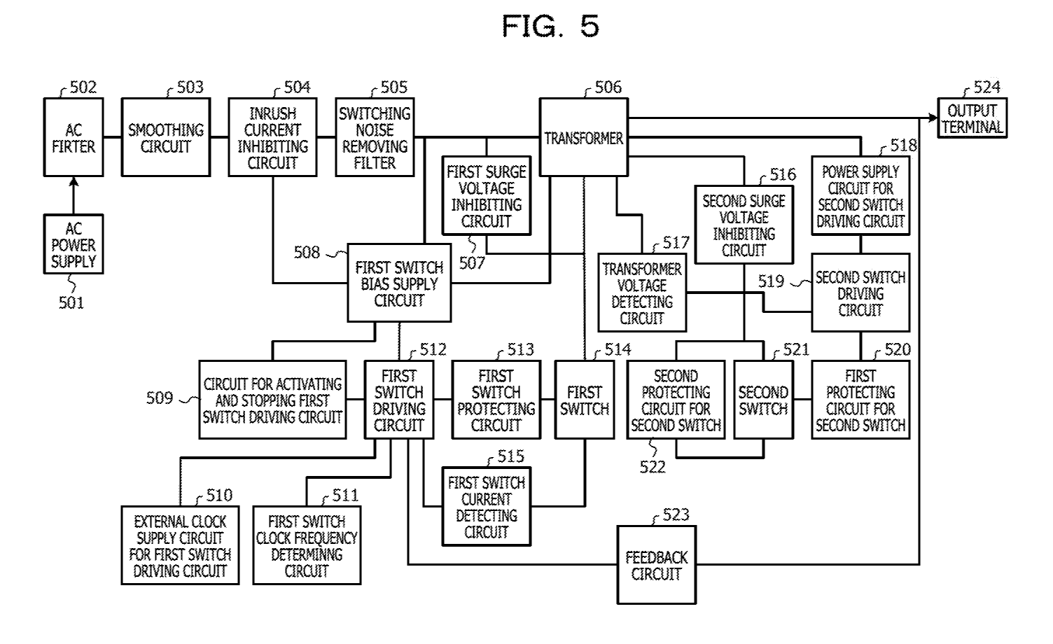

FIG. 1 is a diagram illustrating an example of a configuration of a power supply circuit according to a first embodiment. FIG. 5 is a diagram illustrating an example of a functional configuration of the power supply circuit according to the first embodiment. The power supply circuit according to the first embodiment is a fly-back alternating current (AC) to direct current (DC) switching power supply circuit. For example, the power supply circuit converts an alternating-current voltage of 100 V to a direct current voltage of 5 V. An alternating-current power supply 101 corresponds to an alternating-current power supply 501 illustrated in FIG. 5 and is a commercial power supply such as a household wall socket. For example, the alternating-current power supply 101 supplies an alternating-current voltage of 100 V or 240 V. The frequency of the alternating-current voltage is, for example, 50 Hz or 60 Hz. A series connection circuit having a resistor R45 and an inductor L9 connected to the resistor R45 in series is connected between a first terminal of the alternating-current power supply 101 and an anode of a diode D3. An inductor L8 is connected between a second terminal of the alternating-current power supply 101 and an anode of a diode D4. The resistor R45 and the inductors L8 and L9 correspond to an alternating-current filter 502 illustrated in FIG. 5 and are a filter circuit for removing noise and a waveform shaping circuit for removing a harmonic component. The resistor R45 is also a fuse circuit that is disconnected when a large current flows.

An anode of a diode D5 is connected to a reference potential node, while a cathode of the diode D5 is connected to the anode of the diode D3. The reference potential node is, for example, a ground potential node. A cathode of the diode D3 is connected to an anode of a thyristor SCR. An anode of a diode D6 is connected to the reference potential node, while a cathode of the diode D6 is connected to the anode of the diode D4. A cathode of the diode D4 is connected to the anode of the thyristor SCR. The diodes D3 to D6 are a full-wave rectifier circuit and conduct full-wave rectification on the alternating-current voltage and output the voltage subjected to the full-wave rectification to the anode of the thyristor SCR. The diodes D3 to D6 correspond to a smoothing circuit 503 illustrated in FIG. 5.

A resistor R48 is connected between the anode of the thyristor SCR and a cathode of the thyristor SCR. A gate of the thyristor SCR is connected to a node 122. The thyristor SCR is turned on and off based on a voltage of the node 122. When the power supply circuit is activated, the alternating-current power supply 101 starts to supply the alternating-current voltage and the thyristor SCR is in an OFF state. In this case, a current does not flow in the thyristor SCR and flows through the resistor R48, and electric charges are gradually accumulated in capacitors C1 and C7. This may inhibit an inrush current upon the activation of the power supply circuit. The resistor R48 and the thyristor SCR correspond to an inrush current inhibiting circuit 504 illustrated in FIG. 5.

The capacitor C1 is connected between the cathode of the thyristor SCR and the reference potential node. An inductor L4 is connected to the cathode of the thyristor SCR and a node 121. The capacitor C7 is connected between the node 121 and the reference potential node. The capacitors C1 and C7 and the inductor L4 correspond to a switching noise removing filter 505 illustrated in FIG. 5 and remove switching noise.

A voltage dividing circuit 106 corresponds to a circuit 509, illustrated in FIG. 5, for activating and stopping a first switch driving circuit and includes resistors R2, R6, and R7. The resistor R2 is connected between the node 121 and the node 122. The resistor R6 is connected between the node 122 and a node 123. The resistor R7 is connected between the node 123 and the reference potential node. Voltages obtained by dividing a voltage of the node 121 by the voltage dividing circuit 106 are output from the nodes 122 and 123.

When electric charges are accumulated in the capacitors C1 and C7, the voltage of the node 122 increases and the thyristor SCR is turned on. After the activation of the power supply circuit, the thyristor SCR is turned on and a current flows in the thyristor SCR having low on-resistance.

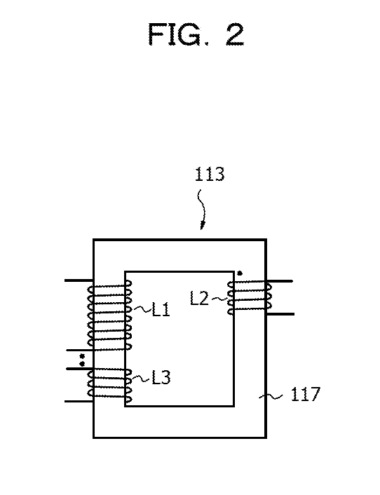

A transformer 113 corresponds to a transformer 506 illustrated in FIG. 5 and includes a primary winding L1, a secondary winding L2, a secondary winding (auxiliary winding) L3, and a core 117. As illustrated in FIG. 2, in the transformer 113, the primary winding L1, the secondary winding L2, and the secondary winding L3 are wound on the core 117. Black points illustrated for the primary winding L1, the secondary winding L2, and the secondary winding L3 indicate winding start points of the primary and secondary windings. The winding start point of the primary winding L1 is on the lower side of the primary winding L1, while the winding start points of the secondary windings L2 and L3 are on the upper sides of the secondary windings L2 and L3. For example, the number of turns of the primary winding L1 is 100, the number of turns of the secondary winding L2 is 10, and the number of turns of the secondary winding L3 is 7.

The primary winding L1 is connected between the node 121 and a drain of a transistor 111. The transistor 111 corresponds to a first switch 514 illustrated in FIG. 5 and is, for example, a gallium nitride (GaN) high electron mobility transistor (HEMT). The HEMT has advantages of resistance to a high voltage and high-speed switching. An anode of a diode D51 is connected to a source of the transistor 111, while a cathode of the diode D51 is connected to the drain of the transistor 111. A resistor R1 corresponds to a first switch current detecting circuit 515 illustrated in FIG. 5 and is connected between the source of the transistor 111 and the reference potential node. The secondary winding L3 is connected between an anode of a diode D1 and the reference potential node. A cathode of the diode D1 is connected to the node 122. The diode D1 is connected to the secondary winding L3 in series. A capacitor C2 is connected between the node 122 and the reference potential node. The node 122 is connected to a power supply terminal VCC of a primary control integrated circuit (IC) 102.

Next, operations of the fly-back transformer 113 are described. The primary control IC 102 is a driving circuit and corresponds to the first switch driving circuit 512 illustrated in FIG. 5 and outputs a pulse with a frequency higher than a frequency (50 Hz or 60 Hz) of the alternating-current power supply 101 to the gate of the transistor 111 via a waveform shaping and protecting circuit 104. Then, the transistor 111 is alternately repeatedly turned on and off. When the transistor 111 is turned on, a current flows in the primary winding L1, a magnetic flux is generated, the core 117 is magnetized, and energy is accumulated in the core 117. When the transistor 111 is turned off, energy accumulated in the core 117 is released and the secondary windings L2 and L3 output power.

The secondary winding L2 is connected between an output terminal 114 and a cathode of a diode D12. An anode of the diode D12 is connected to the reference potential node. The diode D12 corresponds to a second protecting circuit 522, illustrated in FIG. 5, for a second switch. The output terminal 114 corresponds to an output terminal 524 illustrated in FIG. 5. A capacitor C8 is connected between the output terminal 114 and the reference potential node. A pulse voltage is generated across the secondary winding L2, the capacitor C8 smooths the pulse voltage, and a direct-current voltage is applied to the output terminal 114. Similarly, a pulse voltage is generated across the secondary winding L3, the capacitor C2 smooths the pulse voltage, and a direct-current voltage is applied to the node 122.

For example, when the alternating-current voltage of the alternating-current power supply 101 is 100V, a voltage of the node 121 is approximately 141V, a pulse voltage in a range of 30V to 40V is generated across the secondary winding L2, and pulse voltages in a range of 8V to 11V are generated across the secondary winding L3. A target voltage of the output terminal 114 is a direct-current voltage of 5 V.

To reduce a loss caused by a voltage drop of the diode D12, a transistor 112 is mounted. The transistor 112 is, for example, a gallium nitride (GaN) HEMT. A drain of the transistor 112 is connected to the cathode of the diode D12, while a source of the transistor 112 is connected to the anode of the diode D12. Thus, the transistor 112 is connected to the diode D12 in parallel. The transistor 112 corresponds to the second switch 521 illustrated in FIG. 5.

An anode of a Zener diode D7a is connected to the cathode of the diode D12. A resistor R12 is connected between a cathode of the Zener diode D7 and a power supply terminal VCC of a secondary control IC 103. A capacitor C9 is connected between the power supply terminal VCC of the secondary control IC 103 and the reference potential node. A ground terminal GND of the secondary control IC 103 is connected to the reference potential node. Thus, a power supply voltage is applied to the power supply terminal VCC of the secondary control IC 103. The Zener diode D7, the resistor R12, and the capacitor C9 correspond to a power supply circuit 518, illustrated in FIG. 5, for a second switch driving circuit.

A resistor R11 corresponds to a transformer voltage detecting circuit 517 illustrated in FIG. 5 and is connected between the cathode of the diode D12 and a detection terminal IN of the secondary control IC 103. The secondary control IC 103 corresponds to a second switch driving circuit 519 illustrated in FIG. 5. When a voltage of the detection terminal IN is higher than a threshold, the secondary control IC 103 outputs a high-level voltage from an output terminal OUT. When the voltage of the detection terminal IN is lower than the threshold, the secondary control IC 103 outputs a low-level voltage from the output terminal OUT. The output terminal OUT of the secondary control IC 103 outputs a pulse voltage to a gate of the transistor 112 via a waveform shaping and protecting circuit 105.

The waveform shaping and protecting circuit 105 corresponds to a first protecting circuit 520, illustrated in FIG. 5, for the second switch and is connected between the output terminal OUT of the secondary control IC 103 and the gate of the transistor 112. The waveform shaping and protecting circuit 105 shapes an edge of the pulse voltage output by the secondary control IC 103 so that the edge of the pulse voltage is steep in order to causes the transistor 112 to operate at a high speed. The waveform shaping and protecting circuit 105 suppresses overshoot and undershoot of the pulse voltage output by the secondary control IC 103 in order to protect the transistor 112. The waveform shaping and protecting circuit 105 includes diodes D9, D26, and D27, a Zener diode D11, a resistor R13, and a capacitor C26. An anode of the diode D9 is connected to the output terminal OUT of the secondary control IC 103. An anode of the Zener diode D11 is connected to a cathode of the diode D9, while a cathode of the Zener diode D11 is connected to the anode of the diode D9. The resistor R13 is connected between the cathode of the diode D9 and the gate of the transistor 112. An anode of the diode D26 is connected to the gate of the transistor 112, while a cathode of the diode D26 is connected to an anode of the diode D27. The capacitor C26 is connected between a cathode of the diode D27 and the reference potential node.

When a voltage of the gate of the transistor 112 reaches a high level, the transistor 112 is turned on. When the voltage of the gate of the transistor 112 reaches a low level, the transistor 112 is turned off. By turning on the transistor 112, a loss caused by the diode D12 may be reduced.

When the transistor 112 is an HEMT, a switching speed of the transistor 112 is high, dV/dt is large, and a spike voltage generated due to parasitic inductance caused by leakage inductance caused by flux leakage of the transformer 113 and a board wiring is large. A snubber circuit 108 is connected between the output terminal 114 and the drain of the transistor 112. The snubber circuit 108 is a protecting circuit for suppressing a spike voltage (of 400 V to 1 kV) upon the switching of the transistor 112. The snubber circuit 108 corresponds to a second surge voltage inhibiting circuit 516 illustrated in FIG. 5 and includes a capacitor C6, a resistor R17, and a diode D10. The capacitor C6 is connected between the output terminal 114 and a cathode of the diode D10. The resistor R17 is connected to the capacitor C6 in parallel. An anode of the diode D10 is connected to the drain of the transistor 112. The capacitor C6 is charged to absorb the spike voltage (high voltage) upon the switching of the transistor 112. When the transistor 112 is in an OFF state, the capacitor C6 releases electric charges to the resistor R17.

A bias circuit 118 is connected between the output terminal 114 and a photocoupler 109. The photocoupler 109 includes a light emitting diode 115 and a phototransistor 116. An emitter of the phototransistor 116 is connected to the reference potential node. A resistor R5 is connected between the node 122 and a collector of the phototransistor 116. The bias circuit 118 and the photocoupler 109 correspond to a feedback circuit 523 illustrated in FIG. 5.

Next, a configuration of the bias circuit 118 is described. A Zener diode 110 is a voltage reference circuit. An anode of the Zener diode 110 is connected to the reference potential node. A resistor R3 is connected between the output terminal 114 and a node 131. A resistor R10 is connected between the node 131 and a reference terminal of the Zener diode 110. A resistor R4 is connected between the reference terminal of the Zener diode 110 and the reference potential node. A resistor R20 is connected between the output terminal 114 and an anode of the light emitting diode 115. A resistor R18 is connected between the anode of the light emitting diode 115 and a cathode of the light emitting diode 115. A resistor R19 is connected between the cathode of the light emitting diode 115 and a cathode of the Zener diode 110. A series connection circuit having a capacitor C12 and a resistor R21 connected to the capacitor C12 in series is connected between the cathode of the Zener diode 110 and the node 131.

When a voltage of the output terminal 114 increases, the intensity of light emitted by the light emitting diode 115 increases and a current flowing in the phototransistor 116 increases. In this case, the primary control IC 102 reduces a duty ratio of a gate pulse of the transistor 111. The duty ratio of the gate pulse is the ratio of a time period during which the gate pulse is at a high level within a period of the gate pulse to the period of the gate pulse. For example, when the voltage of the output terminal 114 is higher than the target voltage of 5 V, the primary control IC 102 reduces the duty ratio of the gate pulse of the transistor 111. Thus, the voltage of the output terminal 114 decreases.

On the other hand, when the voltage of the output terminal 114 decreases, the intensity of the light emitted by the light emitting diode 115 decreases and the current flowing in the phototransistor 116 decreases. In this case, the primary control IC 102 increases the duty ratio of the gate pulse of the transistor 111. For example, when the voltage of the output terminal 111 is lower than the target voltage of 5 V, the primary control IC 102 increases the duty ratio of the gate pulse of the transistor 111. Thus, the voltage of the output terminal 114 increases. The output terminal 114 is maintained at the fixed target voltage of 5 V.

The power supply terminal VCC of the primary control IC 102 is connected to the node 122. Upon the activation of the power supply circuit, the secondary winding L3 does not output power, a current flows from the node 121 through the resistor R2 to the capacitor C2, and the capacitor C2 is charged. The capacitor C2 supplies a power supply voltage to the power supply terminal VCC of the primary control IC 102, whereby the primary control IC 102 is operable.

After the activation of the power supply circuit, the secondary winding L3 outputs power, a current flows from the secondary winding L3 through the diode D1 to the capacitor C2, and the capacitor C2 is charged. The capacitor C2 supplies a power supply voltage to the power supply terminal VCC of the primary control IC 102, whereby the primary control IC 102 is operable. The resistor R2, the secondary winding L3, the diode D1, and the capacitor C2 correspond to a first switch bias supply circuit 508 illustrated in FIG. 5.

An enable terminal EN of the primary control IC 102 is connected to the node 123. A resistor R8 corresponds to a first switch clock frequency determining circuit 511 illustrated in FIG. 5 and is connected between a frequency control terminal FR of the primary control IC 102 and the reference potential node. An anode of a Zener diode D8 is connected to a current feedback terminal IFB of the primary control IC 102, while a cathode of the Zener diode D8 is connected to the collector of the phototransistor 116. The waveform shaping and protecting circuit 104 has the same configuration as that of the waveform shaping and protecting circuit 105 and is connected between an output terminal OUT of the primary control IC 102 and the gate of the transistor 111. The waveform shaping and protecting circuit 104 corresponds to a first switch protecting circuit 513 illustrated in FIG. 5. A current detection terminal IS of the primary control IC 102 is connected to the source of the transistor 111. A ground terminal GND of the primary control IC 102 is connected to the reference potential node. In FIG. 5, an external clock supply circuit 510 for the first switch driving circuit supplies a clock signal to the first switch driving circuit 512.

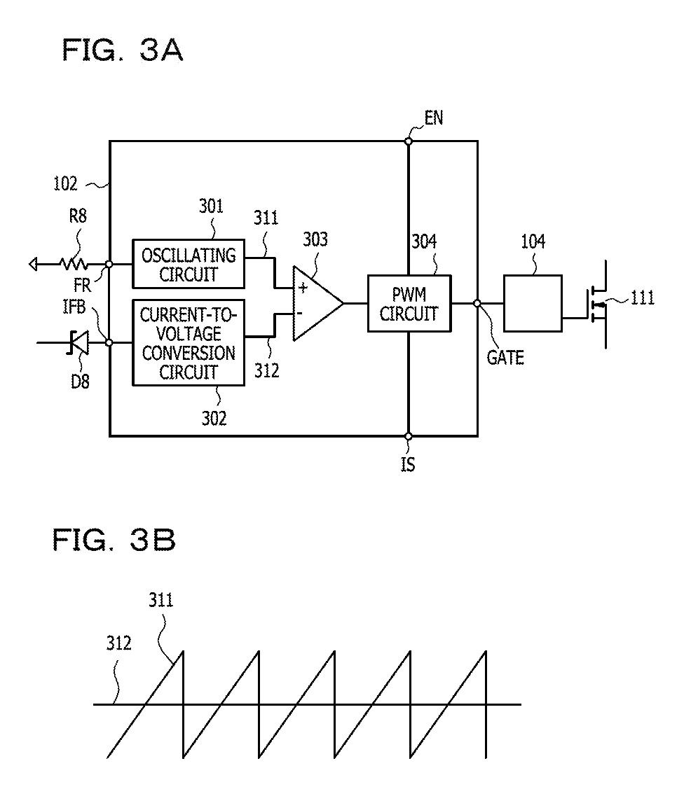

FIG. 3A is a conceptual diagram illustrating an example of a configuration of the primary control IC 102. FIG. 3B is a voltage waveform diagram describing operations of the primary control IC 102. The primary control IC 102 includes an oscillating circuit 301, a current-to-voltage conversion circuit 302, a comparator 303, and a pulse width modulation (PWM) circuit 304. The oscillating circuit 301 is connected to the resistor R8 via the frequency control terminal FR and generates a ramp voltage (sawtooth voltage) 311 with a frequency based on a value of the resistor R8. The resistor R8 is mounted outside the primary control IC 102. By changing the resistor R8, the frequency of the ramp voltage 311 generated by the oscillating circuit 301 may be changed.

For example, when the transistor 111 is an HEMT, the transistor 111 operates at a high speed and the frequency of the ramp voltage 311 may be increased by the resistor R8. When the transistor 111 is a MOS field-effect transistor, the transistor 111 operates at a low speed and the frequency of the ramp voltage 311 may be reduced by the resistor R8.

The current-to-voltage conversion circuit 302 converts, to a voltage 312, the current flowing in the phototransistor 116 through the Zener diode D8. When the ramp voltage 311 is higher than the voltage 312, the comparator 303 outputs a high-level voltage. When the ramp voltage 311 is lower than the voltage 312, the comparator 303 outputs a low-level voltage. When the voltage of the enable terminal EN is higher than a threshold, the PWM circuit 304 is in an enable state and outputs, from the output terminal GATE, the gate pulse with the duty ratio based on an output pulse of the comparator 303. When the PWM circuit 304 detects an overcurrent of the transistor 111 based on the current detection terminal IS, the PWM circuit 304 stops operating. The output terminal GATE outputs the gate pulse to the gate of the transistor 111 via the waveform shaping and protecting circuit 104. When the gate pulse is at the high level, the transistor 111 is in an ON state. When the gate pulse is at the low level, the transistor 111 is in an OFF state.

A time period during which the output pulse of the comparator 303 is at the low level corresponds to a time period during which the transistor 111 is in the ON state. A time period during which the output pulse of the comparator 303 is at the high level corresponds to a time period during which the transistor 111 is in the OFF state. The PWM circuit 304 sets the frequency of the gate pulse to a fixed value and controls the duty ratio of the gate pulse. For example, as the time period during which the output pulse of the comparator 303 is at the low level is longer, the PWM circuit 304 increases the duty ratio of the gate pulse. As the time period during which the output pulse of the comparator 303 is at the low level is shorter, the PWM circuit 304 reduces the duty ratio of the gate pulse.

As described above, when the voltage of the output terminal 114 is higher than the target voltage of 5 V, the primary control IC 102 reduces the duty ratio of the gate pulse. This reduces the voltage of the output terminal 114. When the voltage of the output terminal 114 is lower than the target voltage of 5 V, the primary control IC 102 increases the duty ratio of the gate pulse of the transistor 111. This increases the voltage of the output terminal 114. Thus, the voltage of the output terminal 114 is the fixed target voltage of 5 V. A load is connected to the output terminal 114. The power supply circuit may supply the direct-current power supply voltage of 5 V to the load.

A primary control IC that does not include a frequency control terminal FR is described below as the primary control IC 102. Even when an oscillation frequency of an oscillating circuit of the primary control IC is a fixed value (for example, a low frequency of 50 kHz) and the primary control IC drives a MOS field-effect transistor, the primary control IC may not drive an HEMT at a high speed. When a high-speed transistor such as an HEMT is used as the transistor 111, the primary control IC 102 having the frequency control terminal FR is mounted, as described in the first embodiment. Since the resistor R8 is mounted, the primary control IC 102 may generate a high-frequency gate pulse. Thus, the primary control IC 102 may switch the transistor 111 at a high speed.

It is preferable that the transistors 111 and 112 be high-speed transistors such as HEMTs. As maximum oscillation frequencies fmax, causing a power amplification factor to be 1, of the transistors 111 and 112 and cutoff frequencies ft, causing a current amplification factor to be 1, of the transistors 111 and 112 are higher, the transistors 111 and 112 are more preferable. For example, it is preferable that the maximum oscillation frequencies fmax and the cutoff frequencies ft be seventh or higher harmonics (frequency components enabling rectangular waves) of frequencies to be used for the switching of the transistors 111 and 112. It is preferable that the maximum oscillation frequencies fmax, causing the power amplification factor to be 1, of the transistors 111 and 112 and the cutoff frequencies ft, causing the current amplification factor to be 1, of the transistors 111 and 112 be 10 MHz or higher.

Since the resistor R2, the capacitor C2, the diode D1, and the secondary winding L3 are connected to the power supply terminal VCC of the primary control IC 102, a power supply voltage may be supplied to the power supply voltage VCC of the primary control IC 102 upon and after the activation. When the voltage dividing circuit 106 is connected to the enable terminal EN of the primary control IC 102, the primary control IC 102 may be in an enable state.

When the transistor 111 is an HEMT, the switching speed of the transistor 111 is high, dV/dt is large, and a spike voltage generated due to parasitic inductance caused by leakage inductance caused by flux leakage of the transformer 113 and the board wiring is large. A snubber circuit 107 is connected between the node 121 and the drain of the transistor 111 and is a protecting circuit for suppressing a spike voltage (of 400 V to 1 kV) upon the switching of the transistor 111. The snubber circuit 107 corresponds to a first surge voltage inhibiting circuit 507 illustrated in FIG. 5 and includes a capacitor C5, a resistor R9, and a Zener diode D2. The capacitor C5 is connected between the node 121 and a cathode of the Zener diode D2. The resistor R9 is connected to the capacitor C5 in parallel. An anode of the Zener diode D2 is connected to the drain of the transistor 111. The capacitor C5 is charged to absorb the spike voltage (high voltage) upon the switching of the transistor 111. When the transistor 111 is in the OFF state, the capacitor C5 releases electric charges to the resistor R9.

### Second Embodiment

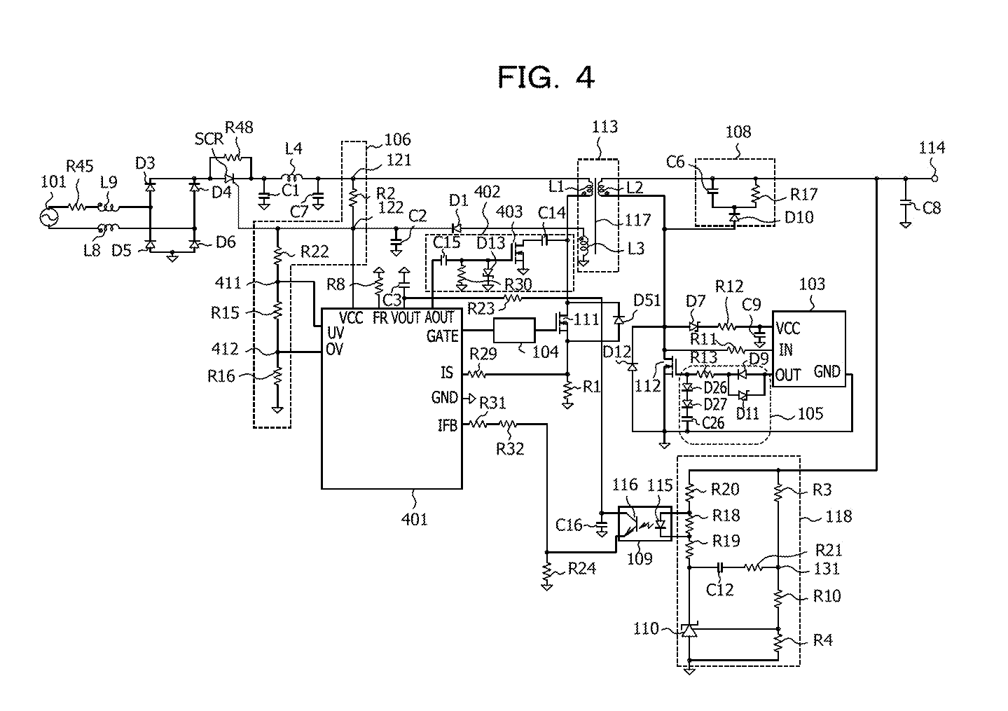

FIG. 4 is a diagram illustrating an example of a configuration of a power supply circuit according to a second embodiment. The power supply circuit according to the second embodiment is a forward alternating current (AC) to direct current (DC) switching power supply circuit. Features of the second embodiment that are different from those of the first embodiment are described below. Since the transformer 113 illustrated in FIG. 1 is of the fly-back type, the winding start point of the primary winding L1 is on the lower side of the primary winding L1, and the winding start points of the secondary windings L2 and L3 are on the upper sides of the secondary windings L2 and L3, as indicated by the black points. On the other hand, since the transformer 113 illustrated in FIG. 4 is of a forward type, the winding start points of the primary and secondary windings L1 and L2 are on the lower sides of the primary and secondary windings L1 and L2, and the winding start point of the secondary winding L3 is on the upper side of the secondary winding L3.

Next, operations of the forward transistor 113 are described. When the transistor 111 is turned on, a current flows in the primary winding L1 and the secondary winding L2 outputs power due to electromagnetic induction. When the transistor 111 is turned off, a current does not flow in the primary winding L1 and the secondary winding L2 does not output power.

A primary control IC 401 is mounted instead of the primary control IC 102 illustrated in FIG. 1. A power supply terminal VCC of the primary control IC 401 is connected to the node 122 in the same manner as illustrated in FIG. 1. A frequency control terminal FR of the primary control IC 401 is connected to the resistor R8 in the same manner as illustrated in FIG. 1. An output terminal OUT of the primary control IC 401 is connected to the gate of the transistor 111 via the waveform shaping and protecting circuit 104 in the same manner as illustrated in FIG. 1. A ground terminal GND of the primary control IC 401 is connected to the reference potential node in the same manner as illustrated in FIG. 1.

A voltage dividing circuit 106 includes the resistor R2 and resistors R22, R15, and R16. The resistor R22 is connected to the node 122 and a node 411. The resistor R15 is connected between the node 411 and a node 412. The resistor R16 is connected to the node 412 and the reference potential node. An undervoltage detection terminal UV of the primary control IC 401 is connected to the node 411. An overvoltage detection terminal OV of the primary control IC 401 is connected to the node 412.

A capacitor C3 is connected between an internal power supply output terminal VOUT of the primary control IC 401 and the reference potential node. A resistor R23 is connected between the internal power supply output terminal VOUT of the primary control IC 401 and the collector of the phototransistor 116. A capacitor C16 is connected between the collector of the phototransistor 116 and the reference potential node.

A resistor R29 is connected between a current detection terminal IS of the primary control IC 401 and the source of the transistor 111. A series connection circuit having resistors R31 and R32 connected to each other in series is connected to a current feedback terminal IFB of the primary control IC 401 and the emitter of the phototransistor 116. A resistor R24 is connected to the emitter of the phototransistor 116 and the reference potential node.

The primary control IC 401 operates in a similar manner to the primary control IC 102 illustrated in FIG. 1. The primary control IC 401 detects an undervoltage of the node 411 based on the undervoltage detection terminal UV and detects an overvoltage of the node 412 based on the overvoltage detection terminal OV. The primary control IC 401 outputs a voltage based on a power supply voltage of the power supply terminal VCC from the internal power supply output terminal VOUT. The primary control IC 401 outputs, from an output terminal AOUT, a high-level pulse that rises immediately before the transistor 111 is changed from the ON state to the OFF state.

An active clamp circuit 402 is mounted instead of the snubber circuit 107 illustrated in FIG. 1 and is connected to the output terminal AOUT of the primary control IC 401 and the drain of the transistor 111. The active clamp circuit 402 connects the drain of the transistor 111 to a capacitor C14 during a period of time when the transistor 111 is changed from the ON state to the OFF state.

The active clamp circuit 402 includes a capacitor C15, a resistor R30, a Zener diode D13, a transistor 403, and the capacitor C14. The transistor 403 is, for example, an HEMT, like the transistor 111. As a maximum oscillation frequency fmax, causing a power amplification factor to be 1, of the transistor 403 and a cutoff frequency ft, causing a current amplification factor to be 1, of the transistor 403 are higher, the transistor 403 is more preferable. For example, it is preferable that the maximum oscillation frequency fmax and the cutoff frequency ft be seventh or higher harmonics (frequency components enabling rectangular waves) of frequencies to be used for the switching of the transistor 403. It is preferable that the maximum oscillation frequency fmax, causing the power amplification factor to be 1, of the transistor 403 and the cutoff frequency ft, causing the current amplification factor to be 1, of the transistor 403 be 10 MHz or higher.

The capacitor C15 is connected between the output terminal AOUT of the primary control IC 401 and a gate of the transistor 403. The resistor R30 is connected between the gate of the transistor 403 and the reference potential node. An anode of the Zener diode D13 is connected to the gate of the transistor 403, while a cathode of the Zener diode D13 is connected to the reference potential node. A source of the transistor 403 is connected to the reference potential node. The capacitor C14 is connected between a drain of the transistor 403 and the drain of the transistor 111.

When a voltage of the gate of the transistor 403 reaches a high level, the transistor 403 is turned on. When the voltage of the gate of the transistor 403 reaches a low level, the transistor 403 is turned off. The output terminal AOUT of the primary control IC 403 outputs a high-level pulse that rises immediately before the transistor 111 is changed from the ON state to the OFF state. The transistor 403 is in an ON state and connects the drain of the transistor 111 to the capacitor C14 during the period of time when the transistor 111 is changed from the ON state to the OFF state. The capacitor C14 may store electric charges at the drain of the transistor 111 to reduce a spike voltage of the drain of the transistor 111.

When the transistor 111 is in the OFF state, an intermediate voltage is applied to the gate of the transistor 403 and the transistor 403 functions as a resistor. The capacitor C14 releases electric charges to the transistor 403 functioning as the resistor.

As described above, according to the first and second embodiments, a power supply voltage may be supplied to the power supply voltage VCC of the primary control IC 102 or 401 upon and after the activation by connecting the resistor R2, the capacitor C2, the diode D1, and the secondary winding L3 to the power supply terminal VCC of the primary control IC 102 or 401.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A power supply circuit comprising:
a transformer that includes a primary winding and a first secondary winding;
a first diode coupled to the first secondary winding in series;
a first node, coupled to the primary winding, for receiving a supplied voltage;
a second node coupled to a series connection circuit, the series connection circuit is including the first secondary winding and the first diode coupled to the first secondary winding in series;
a first capacitor coupled to the second node;
a first resistor coupled between the first node and the second node; and
a driving circuit that includes a power supply terminal coupled to the second node.

2. The power supply circuit according to claim 1, further comprising:
a second resistor coupled between the second node and a third node; and
a third resistor coupled between the third node and a reference potential node,
wherein the third node is coupled to the driving circuit.

3. The power supply circuit according to claim 1, further comprising:
a first transistor coupled to the primary winding,
wherein the driving circuit drives the first transistor.

4. The power supply circuit according to claim 3, further comprising:
a rectifier circuit that rectifies an alternating-current voltage and supplies the rectified voltage to the first node.

5. The power supply circuit according to claim 4, p1 wherein the transformer includes a second secondary winding and a second capacitor coupled to the second secondary winding, and
wherein the driving circuit drives the first transistor based on a voltage of the second capacitor.

6. The power supply circuit according to claim 1, further comprising:
a first snubber circuit, coupled between the first node and the first transistor, for suppressing a spike voltage of the first transistor.

7. The power supply circuit according to claim 1, further comprising:
an active clamp circuit that couples the first transistor to a third capacitor during a period of time when the first transistor is changed from an OFF state to an ON state.

8. The power supply circuit according to claim 5, further comprising:
a second diode coupled to the second secondary winding;
a second transistor coupled to the second diode in parallel; and
a second snubber circuit that suppresses a spike voltage of the second transistor.

9. The power supply circuit according to claim 5,
wherein when the first transistor is turned off, the second secondary winding outputs power.

10. The power supply circuit according to claim 5,
wherein when the first transistor is turned on, the second secondary winding outputs power.

11. The power supply circuit according to claim 3,
wherein a maximum oscillation frequency, causing a power amplification factor to be 1, of the first transistor and a cutoff frequency, causing a current amplification factor to be 1, of the first transistor are 10 MHz or higher.
